(19) United States
(12) Patent Application Publication
(10) Pub. No.: US 2009/0014730 A1
(43) Pub. Date: Jan. 15, 2009

(54) SILICON CARBIDE TRANSISTORS AND METHODS FOR FABRICATING THE SAME

(75) Inventors: Jenn-Gwo Hwu, Taipei City (TW); Kai-Chieh Chuang, Taipei City (TW)

Correspondence Address: QUINTERO LAW OFFICE, PC, 2210 MAIN STREET, SUITE 200, SANTA MONICA, CA, 90405, US

(73) Assignee: NATIONAL TAIWAN UNIVERSITY, TAIPEI (TW)

(21) Appl. No.: 12/168,020

(22) Filed: Jul. 3, 2008

(30) Foreign Application Priority Data
Jul. 11, 2007 (TW) 96125183

(51) Int. Cl. H01L 29/24; H01L 21/04

(52) U.S. Cl. 257/77; 438/790; 438/285; 257/E29.104; 257/E21.066; 257/E21.054

(57) ABSTRACT

An exemplary method for forming an insulator layer over a silicon carbide substrate includes providing a silicon carbide substrate and anodizing the silicon carbide substrate in a liquid ambient at a temperature of not more than 200° C. to form a silicon dioxide layer thereon. Also provided are silicon carbide transistors and methods for fabricating the same.

### CROSS REFERENCE TO RELATED APPLICATIONS

This Application claims priority of Taiwan Patent Application No. 96125183, filed on Jul. 11, 2007, the entirety of which is incorporated by reference herein.

### BACKGROUND

The invention relates to semiconductor conductor fabrication and in particular to silicon carbide transistors and methods for fabricating the same.

Compared with well-known silicon materials, silicon carbide material has a relatively wide band gap and a relatively high thermal stability, thereby making it an appropriate candidate to be applied as a substrate in fabricating semiconductor devices operating at high power and high temperature levels.

When fabricating semiconductor devices using silicon carbide substrate, a silicon dioxide layer is mainly used and formed as a gate insulator layer or a dielectric layer therein. The silicon dioxide layer is conventionally formed over the silicon carbide substrate by thermal oxidation and the material and method is normally applied in semiconductor devices such as metal-oxide semiconductor devices (MOS devices).

Nevertheless, forming the silicon dioxide layer over the silicon carbide substrate by thermal oxidation is problematic. Silicon carbide substrate is typically thermally oxidized at a temperature of about 1175° C., thus forming the silicon dioxide layer. However, due to the materials and processes, silicon oxycarbide of carbide-oxygen bond is also formed as a by-product and deposited between the silicon dioxide layer and silicon carbide substrate interface. Thus, forming defects between the silicon dioxide layer and silicon carbide substrate interface, resulting in poor electrical performances of sequentially formed semiconductor devices over the silicon carbide substrate.

### SUMMARY

Methods for forming an insulator layer over a silicon carbide substrate and silicon carbide transistors and methods for fabricating the same are provided.

An exemplary embodiment of a method for forming an insulator layer over a silicon carbide substrate comprises providing a silicon carbide substrate and anodizing the silicon carbide substrate in a liquid ambient at a temperature of not more than 200° C. to form a silicon dioxide layer thereon.

An exemplary embodiment of a silicon carbide transistor comprises a silicon carbide substrate. A gate stack structure is disposed over a part of the silicon carbide substrate, wherein the gate stack structure comprises a silicon dioxide layer and a conductive layer sequentially stacked over the silicon carbide substrate and the silicon dioxide layer is an anodized layer of the silicon carbide substrate. A pair of source/drain regions is disposed in the silicon carbide substrate at opposite sides of the gate stack structure. A pair of spacers is disposed on a sidewall of the gate stack structure at opposite sides thereof to partially cover the silicon carbide substrate.

An exemplary embodiment of a method for fabricating a silicon carbide transistor comprises providing a silicon carbide substrate. An anodization process is performed to the silicon carbide substrate to form a silicon dioxide layer thereon. An annealing process is performed to the silicon dioxide layer and the silicon carbide substrate. A conductive layer is formed over the silicon dioxide layer. A resist pattern is formed over a part of the conductive layer. An etching process is performed using the resist pattern as an etching mask to remove the portion of the conductive layer and the silicon dioxide layer not covered by the resist pattern and forming a gate stack structure over the silicon carbide substrate. The resist pattern is removed and a pair of source/drain regions is formed in the silicon carbide substrate at opposite sides of the gate stack structure. A pair of spacers is formed on a sidewall of the gate stack structure at opposite sides thereof, wherein the spacers partially cover the silicon carbide substrate.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIGS. 1 and 3-5 are schematic diagrams showing an exemplary method for fabricating a silicon carbide transistor;

FIG. 2 is a schematic view showing an exemplary anodization system for forming a silicon dioxide layer;

FIG. 6 is a diagram showing a relationship between an anodization time performed to a silicon carbide substrate and a capacitance equivalent thickness of a formed silicon dioxide layer;

FIG. 7 is a diagram showing performances between a gate current density and a formed silicon dioxide layer of various capacitance equivalent thicknesses;

FIG. 8 is a diagram showing performances between a gate current density and a gate voltage of a formed silicon dioxide layer of various capacitance equivalent thicknesses; and

FIG. 9 is a diagram showing performances between an equivalent breakdown electric field and accumulated percentage of a formed silicon dioxide layer of various capacitance equivalent thicknesses.

### DESCRIPTION

The following description is of the best-contemplated mode of carrying out the invention. This description is made for the purpose of illustrating the general principles of the invention and should not be taken in a limiting sense. The scope of the invention is best determined by reference to the appended claims.

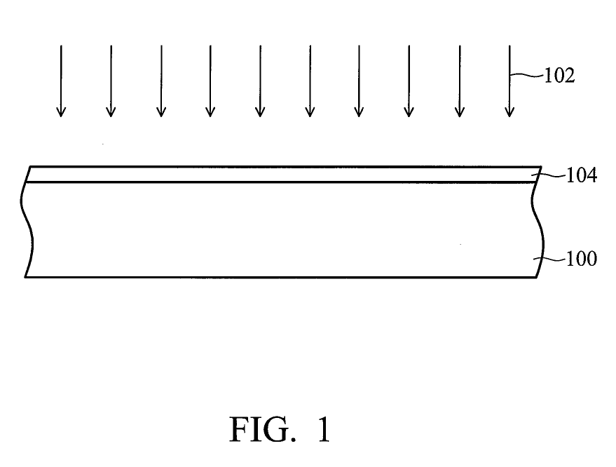

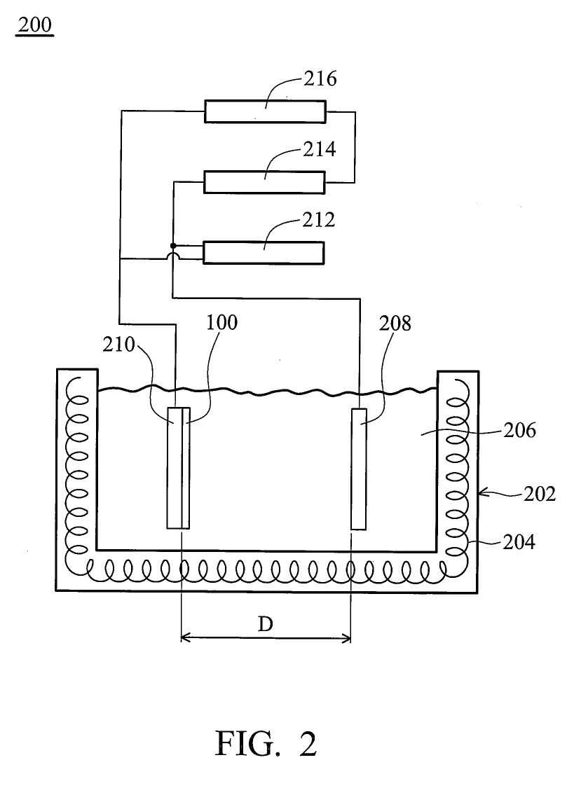

FIGS. 1 and 3-5 are schematic diagrams showing an exemplary method for fabricating a silicon carbide transistor and FIG. 2 is a schematic view showing an exemplary anodization system for forming a silicon dioxide layer.

Referring to FIG. 1, a silicon carbide substrate 100 such as a silicon carbide substrate doped with N type or P type dopants is provided. An anodization process 102 is next performed to the silicon carbide substrate 100 to form a silicon dioxide layer 104 thereon. The silicon dioxide layer 104 is formed with a thickness, for example, of about 26-75 Å and is not limited thereto. It is noted that prior to the anodization process performed to the silicon carbide substrate 100, the silicon carbide substrate 100 is precleaned by a conventional cleaning processes such as standard clean 1 (SC1) using mixtures of H₂O₂, NH₄OH and DI water and stand clean 2 (SC-2) using mixtures of HCl, H₂O₂ and DI water to remove, for example, native oxides and containments thereon and thus provides a clean surface over the silicon carbide substrate 100 to thereby ensure the quality of the sequentially formed silicon dioxide layer 104.

Herein, the anodization process 102 is a wet process performed by, for example, an anodization system 200 as illustrated in FIG. 2. Referring to FIG. 2, an exemplary anodization system 200 is illustrated including a reaction tank 202 with an optional temperature controlling element 204 therein. In addition, the reaction tank 202 is filled with electrolyte solutions 206 such as a solution of DI water. The electrolyte solution 206 may also be organic electrolyte solutions comprise electrolytes such as lithium salts (e.g. LiPF₆, LiClO₄, LiBF₄), fluorine ions (F⁻), and tetraethylammonium bromide (Et4NBr) or inorganic electrolyte solutions comprise electrolytes such as potassium hydroxide (KOH), nitric acid (HNO₃), sulfuric acid (H₂SO₄), and oxalic acid (H₂C₂O₄). Within the anodization system 200, two independent alternative-current (AC) power supplies 212 and 216 are also provided, respectively coupling to an anode electrode 210, wherein the AC power supply 212 may be, for example, an oscillograph and the AC power supply 216 may be, for example, a waveform generator. A direct-current (DC) power supply 214 is provided and coupled between the AC power supplies 212 and 216. The DC power supply 214 can be, for example, pointer type voltage-stabilized power supply, digital type voltage-stabilized power supply, or programmable type voltage-stabilized power supply. The DC power supply 214 is coupled to the cathode electrode 208 and the AC power supplies 216 and 212. Herein, the anode electrode 210 and the cathode electrode 208 can be, for example, a platinum (Pt) electrode.

During the anoization process 102 illustrated in FIG. 1, a non-active surface (not shown), not for forming devices thereon, of the silicon carbide substrate 100 is disposed over the anode electrode 210 and the silicon carbide substrate 100 and then totally immersed within the electrolyte solution 206. An AC voltage and a DC voltage are therefore provided at a space between the anode electrode 210 and the cathode electrode 208. Herein, an active surface (e.g. the surface for forming device thereon, not shown) of the silicon carbide substrate 100 is insulated from the anode electrode 210, and the anode electrode 210 and the cathode 208 is spaced apart for a distance D of about 2-10 cm from each other. The AC power supply 214 and the DC power supply 216 and/or 212 therefore anodize the silicon carbide substrate 100 by a fixed voltage or a fixed current. A temperature of the electrolyte solution 206 is controlled to not more than 200° C. and preferably of about 20-100° C. by the temperature controlling element 204 to thereby form a silicon dioxide layer on the silicon carbide substrate 100. While using fixed voltage methods, the silicon carbide substrate 100 may be anodized by ways such as DC only, AC only, or both DC and AC. During the anodization process 102, the DC power supply 214 provides a voltage of about 20-50 volts, and the AC power supply 216 and/or 212 provides a voltage of about 1-5 volts under a frequency of about 100-1M Hz. The anodization process 102 may be performed for a period of about 20-300 minutes and operation time thereof can be suitably adjusted according to a desired thickness of a formed silicon dioxide layer. Thus, electrical field strength of about 10-25 volts/cm may be provided between the anode electrode 210 and the cathode anode 208 during the anodization process 102.

Referring to FIG. 3, after formation of the silicon dioxide layer 104 over an active surface (not shown) of the silicon carbide substrate 210 by the anodization process 210, an annealing process 106 such as a furnace annealing process or a rapid thermal annealing (RTA) process is then performed under a gaseous ambient comprising hydrogen, nitrogen, oxygen, ammonia gases, and/or nitrous oxide gases and under a temperature of about 850-1200° C. to anneal the silicon carbide substrate 100 and the silicon dioxide layer 104 thereon. While using the furnace annealing process, the annealing process takes a time of about 1-90 minutes. While using the RTA process, the annealing process takes a time of about 0-60 seconds. Through the annealing process 106, defects between the silicon dioxide layer 104 and the silicon carbide substrate 100 interface can be eliminated and performances of sequentially formed semiconductor devices may be thus be improved.

Referring to FIG. 4, a conductive layer 108 is then blanketly formed over the silicon dioxide layer 104. The conductive layer 108 comprises conductive materials such as doped polysilicon, metals such as tungsten (W), or composite materials thereof and can be formed by methods such as chemical vapor deposition (CVD) or physical vapor deposition (PVD). After formation of the conductive layer 108, a patterned resist layer 110 is formed over a portion of the conductive layer 108 to function as a pattern for forming a gate structure.

Referring to FIG. 5, an etching process (not shown) is then performed to remove the portion of the conductive layer 108 and the silicon dioxide layer 104 not covered by the resist layer 110 using the resist layer 110 as an etching mask, thereby forming a patterned conductive layer 108a and a patterned silicon dioxide layer 104a over the silicon carbide substrate 100. The patterned conductive layer 108a and the patterned silicon dioxide layer 104a are stacked over the silicon carbide substrate 100 and thus form a gate stack structure. Next, a pair source/drain regions 112 is formed in the silicon carbide substrate adjacent to the gate stack structure at opposing sides thereof and a pair of spacers is formed over a sidewall of the gate stack structure at opposing sides thereof by conventional transistor fabrication techniques, thereby forming an exemplary silicon carbide transistor. As shown in FIG. 5, portions of the source/drain regions 112 can be further extend to a portion of the silicon carbide substrate 100 under the gate stack structure. The source/drain regions 112 can be doped by P type or N type dopants and the dopants therein have a conductivity type opposite to that of the silicon carbide substrate 100.

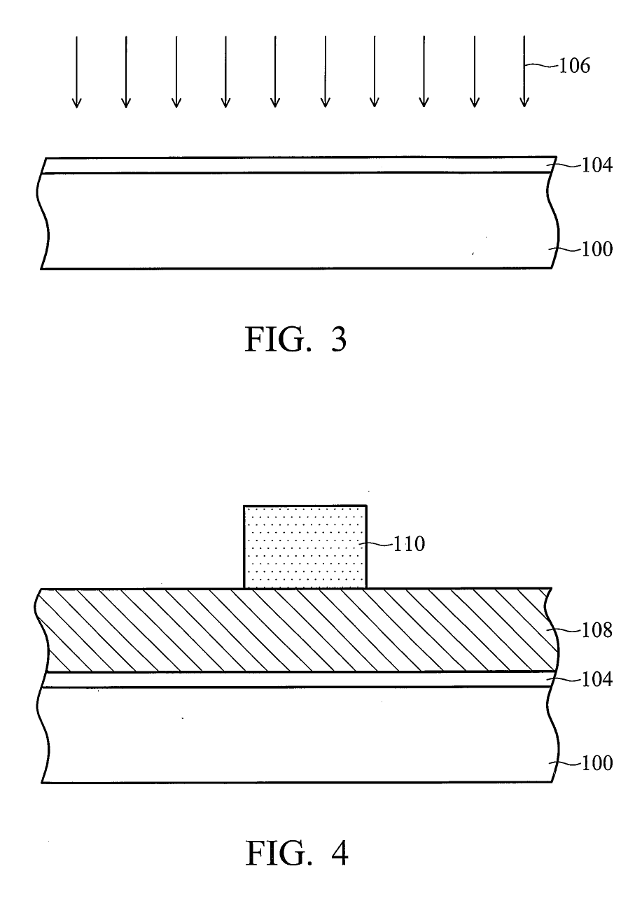

FIGS. 6-9 are various diagrams showing film performances of a silicon dioxde layer formed over a 4H silicon carbide substrate by the above described anodization process. Herein, the silicon carbide substrate is first precleaned and rinsed by DI water prior to the anodization process and then subjected to the anodization system illustrated in FIG. 2 to thereby form a silicon dioxide layer thereon. The electrolyte solutions used in the anodization system is DI water.

FIG. 6 is a diagram showing a relationship between an anodization time performed to a silicon carbide substrate and a capacitance equivalent thickness of a formed silicon dioxide layer is illustrated. Referring to FIG. 6, as the anodization time increases, a thickness of a formed silicon dioxide layer also increases. FIG. 6 shows a substantially linear relation when the anodization time is less than 200 minutes and an interfacial reaction between the silicon dioxide layer and the silicon carbide substrate at the rate determining step and oxygen atoms can steadily diffuse within an interface between thereof. Herein, the thickness of the silicon dioxide layer is measured by a capacitance equivalent method and the thicknesses in FIG. 6 are entitled as a capacitance equivalent thickness.

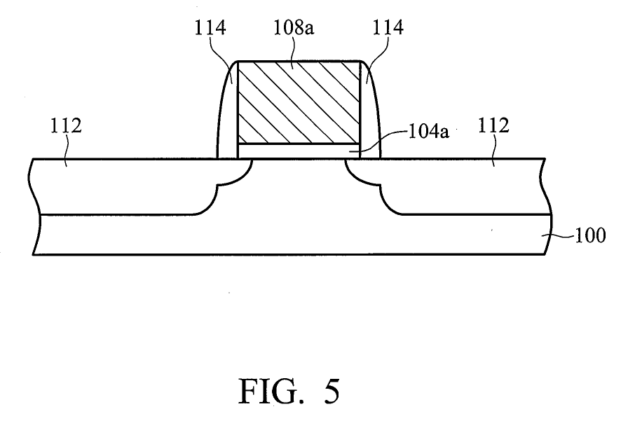

FIG. 7 is a diagram showing performances of a gate current density of a formed silicon dioxide layer at various capacitance equivalent thicknesses measured by a transistor structure similar with that illustrated in FIG. 5 is illustrated. The measurement is obtained under a gate voltage of about 1.5 volts and the silicon dioxide layer of the transistor is about 28 Å, 33 Å or 47 Å, respectively. Referring to FIG. 7, gate current reduces as a thickness of the silicon dioxide layer increases, thereby showing the silicon dioxide layer formed by the anodization process has characteristics for functioning as a gate insulator layer.

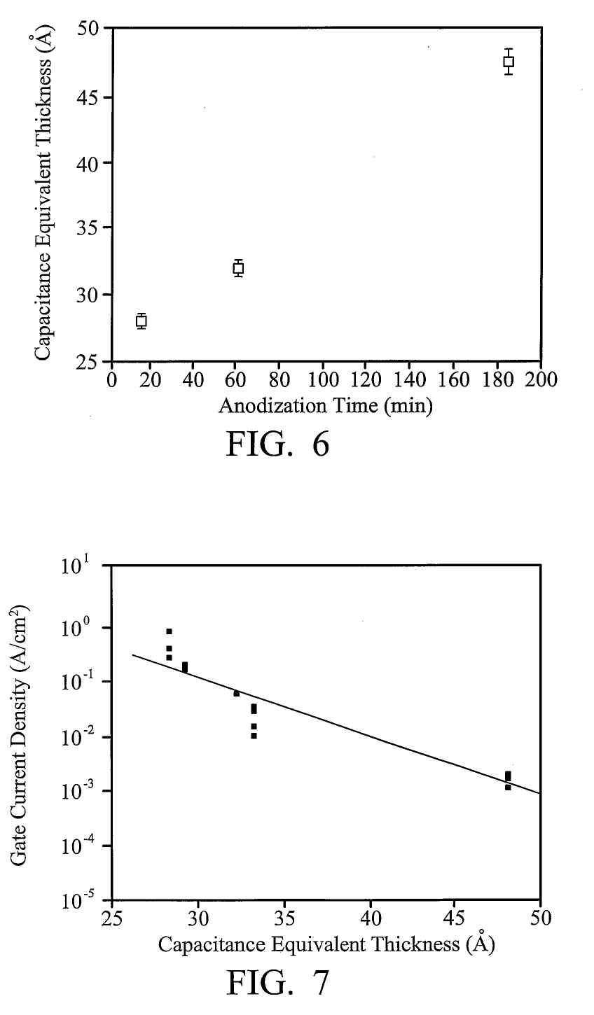

Referring to FIG. 8, a diagram illustrates performances between a gate current density and gate voltages of a formed silicon dioxide layer of various thicknesses (i.e 28 Å, 33 Å and 48 Å.). As shown in FIG. 8, the effective oxide breakdown field of 5.54 MV/cm (48 Å), 6.24 MV/cm (33 Å) and 6.74 MV/cm (28 Å) in the positively biased region, i.e. accumulation region are respectively calculated by using the capacitance effective field method. As shown in FIG. 8, the gate current reduces as a thickness of the silicon dioxide layer increases, thereby showing the silicon dioxide layer formed by the anodization process meets the characteristics of an insulator layer.

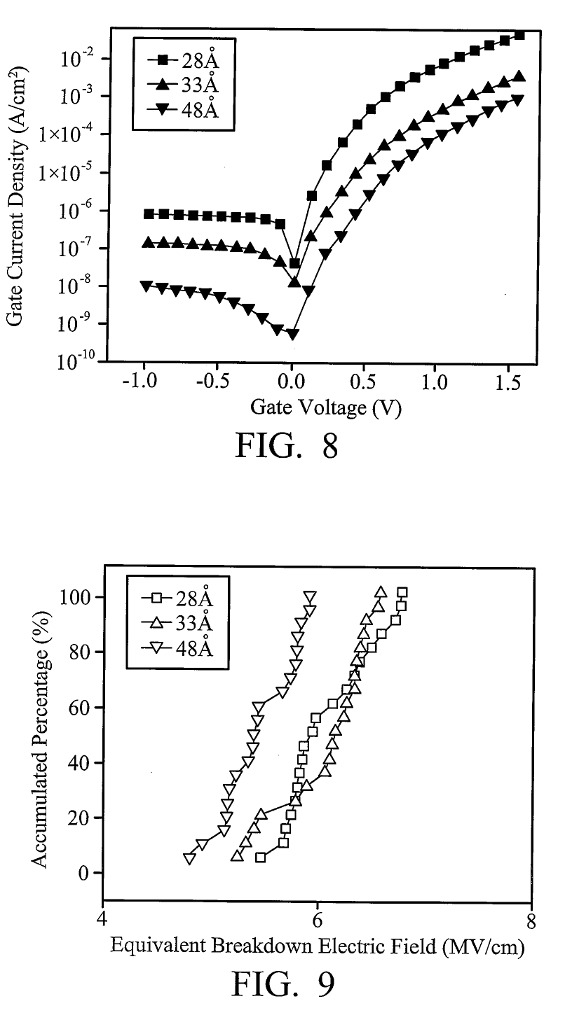

Referring to FIG. 9, a diagram illustrates a relationship between an equivalent breakdown electric field and accumulated percentages of a formed silicon dioxide layer of various capacitance equivalent thicknesses. As shown in FIG. 9, a breakdown field of various silicon dioxide thicknesses at accumulated percentage 50% are about 5.48 MV/cm (48 Å), 5.93 MV/cm (33 Å) and 6.21 MV/cm (28 Å), respectively. The performances are all greater than 5 MV/cm and meets basic requirement for a gate insulator layer for most modern transistors.

As described above, the exemplary method for forming silicon dioxide layer over the silicon carbide substrate can be performed under a relatively low temperature which is not more than 200° C. and can be even performed near room temperature to thereby obtain a silicon dioxide layer of good film characteristics. The film-forming temperature is much less than the conventional thermal oxidation method which typically operates at a temperature of over 1000° C., thus preventing formations of undesired solid silicon oxycarbide by-product of carbide-oxygen bonds at an interface between the silicon dioxide layer and the silicon carbide substrate. This is advantageous for improving electrical performances of a sequentially formed semiconductor device. In addition, the exemplary method for forming an insulator layer over the silicon carbide substrate is cost effective and a silicon dioxide insulating layer can be formed with reduced costs. The above silicon dioxide insulating layer can be applied in fabrication of related applications of semiconductor device using silicon carbide transistors, thereby reducing fabrication costs thereof.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A silicon carbide transistor, comprising:
a silicon carbide substrate;
a gate stack structure disposed over a part of the silicon carbide substrate, wherein the gate stack structure comprises a silicon dioxide layer and a conductive layer sequentially stacked over the silicon carbide substrate and the silicon dioxide layer is an anodized layer of the silicon carbide substrate;
a pair of source/drain regions disposed in the silicon carbide substrate at opposite sides of the gate stack structure; and
a pair of spacers disposed on a sidewall of the gate stack structure at opposite sides thereof, partially covering the silicon carbide substrate.

2. The silicon carbide transistor as claimed in claim 1, wherein the silicon carbide substrate is doped by P-type or N-type dopants.

3. The silicon carbide transistor as claimed in claim 2, wherein the source/drain regions comprises dopants of conductive type opposite to that of the silicon carbide substrate.

4. The silicon carbide transistor as claimed in claim 1, wherein the conductive layer comprises doped polysilicon, metal or composite thereof.

5. A method for fabricating a silicon carbide transistor, comprising:
providing a silicon carbide substrate;
performing an anodization process to the silicon carbide substrate, forming a silicon dioxide layer thereon;
performing an annealing process to the silicon dioxide layer and the silicon carbide substrate;
forming a conductive layer over the silicon dioxide layer;
forming a resist pattern over a part of the conductive layer;
performing an etching process using the resist pattern as an etching mask, removing the portion of the conductive layer and the silicon dioxide layer not covered by the resist pattern, forming a gate stack structure over the silicon carbide substrate; and
removing the resist pattern and forming a pair of source/drain regions in the silicon carbide substrate at opposite sides of the gate stack structure and a pair of spacers on a sidewall of the gate stack structure at opposite sides thereof, wherein the spacers partially cover the silicon carbide substrate.

6. The method as claimed in claim 5, wherein performing the anodization process to the silicon carbide substrate and forming the silicon dioxide layer thereon comprises:
providing an anodization system, comprising:
a reaction tank;
an electrolyte solution filled in the reaction tank;
an anode electrode and a cathode electrode disposed in the electrolyte solution and away from each other;
a direct-current (DC) power supply coupled to the cathode electrode; and
a first alternating-current (AC) power supply coupled to the anode electrode and the DC power supply;
disposing the silicon carbide substrate on the anode electrode and immersing thereof into the electrolyte solution; and
providing a direct-current (DC) voltage by the DC power supply and an alternating-current (AC) voltage by the first AC power supply to a space between the anode electrode and the cathode electrode to perform the anodization process, thereby forming the silicon dioxide layer.

7. The method as claimed in claim 6, further comprising a second alternating-current (AC) power supply coupled to the anode electrode and the cathode electrode.

8. The method as claimed in claim 6, wherein the first AC power supply is a waverform generator.

9. The method as claimed in claim 7, wherein the second AC power supply is an oscillograph.

10. The method as claimed in claim 6, wherein the DC power supply is a pointer type voltage-stabilized power supply, digital type voltage-stabilized power supply, or programmable type voltage-stabilized power supply.

11. The method as claimed in claim 6, further comprising a temperature controlling element disposed in the reaction tank to control a temperature of the electrolyte solution.

12. The method as claimed in claim 6, wherein the electrolyte solution comprises DI water, organic electrolyte solutions or inorganic electrolyte solutions.

13. The method as claimed in claim 5, wherein the annealing process is a furnace annealing process or a rapid thermal annealing (RTA) process.

14. The method as claimed in claim 13, wherein the furnace annealing process performs for about 1-90 minutes.

15. The method as claimed in claim 13, wherein the RTA process performs for about 1-60 seconds.

16. The method as claimed in claim 6, wherein the annealing process is performed under a temperature of about 850-1200° C.

17. The method as claimed in claim 6, wherein the anodization process is performed under a temperature of not more than 200° C.

18. A method for forming an insulating layer over a silicon carbide substrate, comprising:
providing a silicon carbide substrate; and
anodizing the silicon carbide substrate in a liquid ambient at a temperature of not more than 200° C., forming a silicon dioxide layer thereon.

19. The method as claimed in claim 18, wherein anodizing the silicon carbide substrate in the liquid ambient at the temperature of not more than 200° C. and forming the silicon dioxide layer thereon comprises:
providing an anodization system, comprising:
a reaction tank;
an electrolyte solution disposed in the reaction tank;
a temperature controlling element disposed in the reaction tank, controlling a temperature of the electrolyte solution of not more than 200° C.;
an anode electrode and a cathode electrode disposed in the electrolyte solution and away from each other;
a direct-current (DC) power supply coupled to the cathode; and
a first alternating-current (AC) power supply coupled to the anode electrode and the DC power;
disposing the silicon carbide substrate on the anode electrode and immersing the silicon carbide substrate into the electrolyte solution; and
providing a direct-current (DC) voltage by the DC power supply and an alternating-current voltage by the first AC power supply to a space between the anode electrode and the cathode electrode to anodize the silicon carbide substrate, thereby forming the silicon dioxide layer.

20. The method as claimed in claim 19, further comprising a second alternating-current (AC) power supply coupled to the anode electrode and the cathode electrode.

21. The method as claimed in claim 19, wherein the first AC power supply is a waverform generator.

22. The method as claimed in claim 20, wherein the second AC power supply is an oscillograph.

23. The method as claimed in claim 19, wherein the DC power supply is a pointer type voltage-stabilized power supply, digital type voltage-stabilized power supply, or programmable type voltage-stabilized power supply.

24. The method as claimed in claim 19, wherein the electrolyte solution comprises DI water, organic electrolyte solutions or inorganic electrolyte solutions.
